(19) United States
(12) Patent Application Publication
(10) Pub. No.: US 2026/0371873 A1
(43) Pub. Date: Nov. 19, 2026

(54) DISPLAY PANEL AND MANUFACTURING METHOD THEREFOR, AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Wulin SHEN, Beijing (CN); Xilei CAO, Beijing (CN); Yao HUANG, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 19/475,450

(22) PCT Filed: Sep. 11, 2024
(86) PCT No.: PCT/CN2024/118357

§ 371 Date: Oct. 15, 2025

(30) Foreign Application Priority Data
Dec. 14, 2023 (CN) 202311726936.8

(51) Int. Cl. H10K 59/131; H10K 59/12; H10K 59/122; H10K 59/80

(52) U.S. Cl. CPC H10K 59/131; H10K 59/1201; H10K 59/122; H10K 59/80516

(57) ABSTRACT

A display panel includes a backplane and a light-emitting unit layer on the backplane. The light-emitting unit layer includes a first electrode layer, a pixel defining layer, a light-emitting function layer and a second electrode layer. The first electrode layer includes first electrodes and an auxiliary electrode which are electrically insulated from each other. The pixel defining layer includes first openings corresponding to the first electrodes and a second opening corresponding to the auxiliary electrode; the first openings expose at least parts of the first electrodes, and the second opening exposes at least part of the auxiliary electrode. The light-emitting function layer includes a third opening communicated with the second opening, and the second electrode layer is electrically connected to the auxiliary electrode through the third opening and the second opening which are communicated. The auxiliary electrode, the second opening and the third opening are located in a display area.

### CROSS-REFERENCE TO RELATED APPLICATIONS

This application is a national phase entry under 35 USC 371 of International Patent Application No. PCT/CN2024/118357, filed on Sep. 11, 2024, which claims priority to Chinese Patent Application No. 202311726936.8, filed on Dec. 14, 2023, each are incorporated herein by reference in their entirety.

### TECHNICAL FIELD

The present disclosure relates to the field of display technologies, and in particular, to a display panel and a method for manufacturing the same, and a display device.

### BACKGROUND

Organic light-emitting diodes (OLEDs) have been widely used in the display field due to self-luminescence, low driving voltage, high luminous efficiency, fast response speed, being capable of flexible display and other advantages.

### SUMMARY

In an aspect, a display panel is provided. The display panel includes a backplane and a light-emitting unit layer disposed on the backplane. The light-emitting unit layer includes a first electrode layer, a pixel defining layer, a light-emitting functional layer and a second electrode layer that are sequentially arranged in a direction away from the backplane. The first electrode layer includes a plurality of first electrodes and at least one auxiliary electrode, and the plurality of first electrodes are electrically insulated from the at least one auxiliary electrode. The pixel defining layer includes a plurality of first openings disposed corresponding to the plurality of first electrodes, and at least one second opening disposed corresponding to the at least one auxiliary electrode; each first opening exposes at least part of a first electrode, and a second opening exposes at least part of an auxiliary electrode. The light-emitting functional layer includes at least one third opening, a third opening is communicated with the second opening, and the second electrode layer is electrically connected to the auxiliary electrode through the third opening and the second opening that are communicated. The at least one auxiliary electrode, the at least one second opening and the at least one third opening are all located in the display area.

In some embodiments, an orthogonal projection of the third opening on the backplane falls within an orthographic of the auxiliary electrode on the backplane, and an edge of the third opening and an edge of the auxiliary electrode have a distance therebetween.

In some other embodiments, a first electrode and the auxiliary electrode that are adjacent have a distance W1 therebetween, and W1≥2 μm.

In some embodiments, the light-emitting unit layer covers a sidewall of the second opening.

In some embodiments, the display panel includes a plurality of sub-pixels located in the display area, and each sub-pixel includes a first electrode, a portion of the light-emitting functional layer corresponding to the first electrode and a portion of the second electrode layer corresponding to the first electrode. The second opening and the third opening are located between two adjacent sub-pixels, and a whole of the second opening and the third opening and an adjacent sub-pixel have a gap therebetween.

In some embodiments, the light-emitting functional layer includes a plurality of third openings, and the plurality of third openings are evenly distributed in the display area.

In some embodiments, a distance between centers of the plurality of third openings is greater than or equal to 0.1 mm and less than or equal to 10 mm.

In some embodiments, an orthogonal projection of the third opening on the backplane falls within an orthogonal projection of the second opening on the backplane. A center of the third opening and an edge of the third opening have a distance W2 therebetween, and W2≥8 μm.

In some embodiments, centers of the second opening and the third opening coincide with each other. A center of the second opening and an edge of the auxiliary electrode have a distance W3 therebetween, and W3≥9.5 μm.

In some embodiments, the backplane includes a base substrate, a first source-drain conductive layer and a first planarization layer. The first source-drain conductive layer is disposed between the base substrate and the first electrode layer, and the first source-drain conductive layer includes a first conductive pattern located in the display area. The first planarization layer is disposed between the first source-drain conductive layer and the first electrode layer. The planarization layer includes a fourth opening, and the auxiliary electrode is electrically connected to the first conductive pattern through the fourth opening.

In some embodiments, the backplane further includes a gate conductive layer disposed between the first source-drain conductive layer and the base substrate. The gate conductive layer includes a second conductive pattern located in the display area, and the second conductive pattern is electrically connected to the first conductive pattern.

In some embodiments, the backplane further includes a second source-drain conductive layer disposed between the first planarization layer and the first electrode layer, and a second planarization layer disposed between the second source-drain conductive layer and the first electrode layer. The second source-drain conductive layer includes a third conductive pattern located in the display area. The second planarization layer includes a fifth opening, the auxiliary electrode is electrically connected to the third conductive pattern through the fifth opening, and the third conductive pattern is electrically connected to the first conductive pattern through the fourth opening.

In some embodiments, at least one of the first conductive pattern, the second conductive pattern and the third conductive pattern is a VSS auxiliary signal line.

In some embodiments, a pixel density of the display panel is greater than or equal to 450 PPI.

In another aspect, a display device is provided. The display device includes the display panel as described in any of the above embodiments and a circuit board. The circuit board is electrically connected to the display panel.

In some embodiments, the second electrode layer includes a plurality of second electrodes that are connected to one another; or the second electrode layer has a whole layer of film layer structure.

In some embodiments, the display panel further includes at least one third electrode disposed on a side of the second electrode layer away from the backplane, and the at least one third electrode is disposed corresponding to the first electrode and/or corresponding to the auxiliary electrode.

In another aspect, a method for manufacturing a display panel is provided. The method includes following steps.

A first electrode layer is formed on a backplane, where the first electrode layer includes a plurality of first electrodes and an auxiliary electrode, and the plurality of first electrodes are electrically insulated from the auxiliary electrode.

A pixel defining layer is formed on the first electrode layer, where the pixel defining layer includes a plurality of first openings disposed corresponding to the plurality of first electrodes, and a second opening disposed corresponding to the auxiliary electrode; each first opening exposes at least part of a first electrode, and the second opening exposes at least part of the auxiliary electrode.

A light-emitting functional layer is formed on the pixel defining layer, and a portion of the light-emitting functional layer is removed by laser etching to form a third opening in the light-emitting functional layer that that is communicated with the second opening.

A second electrode layer is formed on the light-emitting functional layer, where the second electrode layer is electrically connected to the auxiliary electrode through the third opening and the second opening that are communicated.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display device, in accordance with some embodiments;

FIG. 2 is a plan structural diagram of a display device, in accordance with some embodiments;

FIG. 3 is a sectional view showing a structure of a display panel taken along a section line CC in FIG. 2, in accordance with some embodiments;

FIG. 4 is a sectional view showing a structure of a display panel taken along a section line DD in FIG. 2, in accordance with some embodiments;

FIG. 5 is a flow diagram of a method for manufacturing a display panel, in accordance with some embodiments;

FIG. 6 is a sectional view showing a structure corresponding to steps A1 and A2 in the manufacturing method in FIG. 5;

FIG. 7 is a sectional view showing a structure corresponding to a step A3 in the manufacturing method in FIG. 5;

FIG. 8 is a sectional view showing a structure corresponding to a step A4 in the manufacturing method in FIG. 5;

FIG. 9 is a sectional view showing a structure corresponding to a step A5 in the manufacturing method in FIG. 5;

FIG. 10 is a flow diagram of another method for manufacturing a display panel, in accordance with some embodiments;

FIG. 11 is a sectional view showing a structure corresponding to steps S1 and S2 in the manufacturing method in FIG. 10;

FIG. 12 is a sectional view showing a structure corresponding to a step S3 in the manufacturing method in FIG. 10;

FIG. 13 is a sectional view showing a structure corresponding to a step S4 in the manufacturing method in FIG. 10;

FIG. 14 is another sectional view showing a structure of a display panel taken along a section line CC in FIG. 2, in accordance with some embodiments;

FIG. 15 is a partial enlarged view of a display area of a display panel, in accordance with some embodiments;

FIG. 16 is an enlarged view showing a structure of an area F in FIG. 13;

FIG. 17 is another sectional view showing a structure of a display panel taken along a section line CC in FIG. 2, in accordance with some embodiments;

FIG. 18 is another sectional view showing a structure of a display panel taken along a section line CC in FIG. 2, in accordance with some embodiments;

FIG. 19 is another sectional view showing a structure of a display panel taken along a section line CC in FIG. 2, in accordance with some embodiments; and

FIG. 20 is a plan structural diagram of a display device, in accordance with some embodiments.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” is construed as open and inclusive, i.e., “including, but not limited to”. In the description of the specification, the terms such as “one embodiment”, “some embodiments”, “exemplary embodiments”, “example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. The term “connection” should be understood in a broad sense. For example, the “connection” may be a fixed connection, a detachable connection, or of an integrated structure; it may be a direct connection or an indirect connection by an intermediate medium. The term “coupled” indicates, for example, that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in a device, and are not intended to limit the scope of the exemplary embodiments.

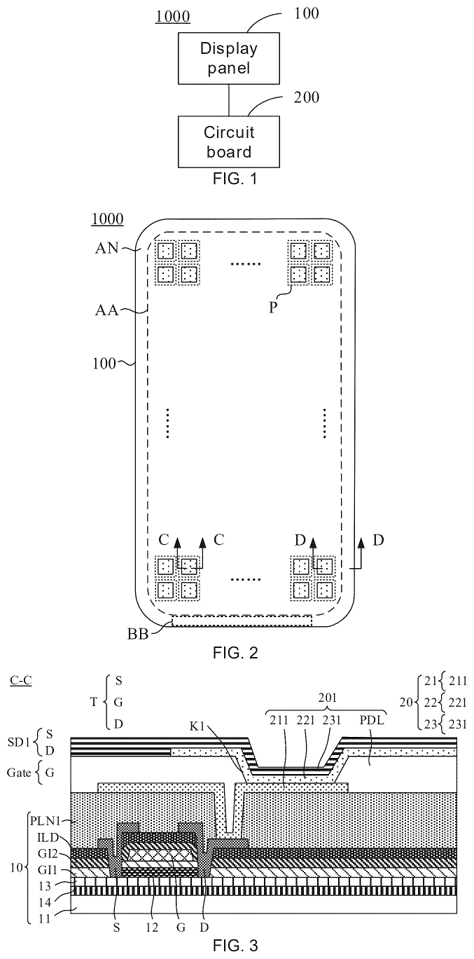

As shown in FIG. 1, some embodiments of the present disclosure provide a display device 1000. The display device 1000 may be any device that displays images whether in motion (such as a video) or fixed (such as a still image), and regardless of text or image. More specifically, it is expected that the embodiments may be implemented in or associated with a variety of electronic devices. The variety of electronic devices may include (but are not limited to), for example, a mobile phone, a wireless device, a personal digital assistant (PDA), a hand-held or portable computer, a global positioning system (GPS) receiver/navigator, a camera, an MPEG-4 Part 14 (MP4) video player, a video camera, a game console, a watch, a clock, a calculator, a TV monitor, a flat-panel display, a computer monitor, a car display (e.g., an odometer display), a navigator, a cockpit controller and/or display, a camera view display (e.g., a display of a rear view camera in a vehicle), an electronic photo, an electronic billboard or sign, a projector, an architectural structure, a packaging and aesthetic structure (e.g., a display for displaying an image of a piece of jewelry), etc.

The display device 1000 includes a display panel 100 and a circuit board 200. The display panel 100 is electrically connected to the circuit board 200. The display device 1000 may further include a frame and other electronic components. For example, the display panel 100 is disposed inside the frame.

The circuit board 200 is configured to send driving signals, such as a display driving signal and/or a touch driving signal, to the display panel 100. The display panel 100 displays images and/or implements touch operations under drive of the circuit board 200.

The circuit board 200 includes, but is not limited to, a printed circuit board (PCB) or a flexible printed circuit (FPC).

The display panel 100 includes, but is not limited to, an organic light-emitting diode (OLED) display panel, a quantum dot light-emitting diode (QLED) display panel, or a micro light-emitting diode (micro LED) display panel, which is not specifically limited in the present disclosure.

The type of the display panel 100 varies, and may be selected depending on actual needs. Some embodiments of the present disclosure will be described below by considering an example in which the display panel 100 is the OLED display panel.

In some embodiments, as shown in FIG. 2, the display panel 100 includes a display area AA and a peripheral area AN located on at least one side of the display area AA. The peripheral area AN includes a bonding region BB. The bonding region BB is located on a side of the display panel 100 for being connected to the circuit board 200. The circuit board 200 is electrically connected to the display panel 100 in the bonding region BB.

The peripheral area AN may be located on one side of the display area AA, or on two adjacent or opposite sides of the display area AA, or surround the display area AN. Adaptive design may be carried out specifically as needed, and limitations are not made in the present disclosure.

Based on this, in some examples, as shown in FIG. 2, the display panel 100 includes a display area AA and a peripheral area AN surrounding the display area AA. The bonding region BB and the circuit board 200 are located on the same side of the display area AA, and the circuit board 200 is electrically connected to the display panel 100 in the bonding region BB. In some other examples, the display panel 100 includes a peripheral area AN located on a side of the display area AA. At least a portion of the peripheral area AN is the bonding region BB, and the circuit board 200 is electrically connected to the display panel 100 in the bonding region BB.

In some embodiments, as shown in FIG. 2, the display area AA is provided with a plurality of pixels therein, and each pixel includes at least three sub-pixels P of different colors.

Based on this, in some examples, as shown in FIG. 2, each pixel includes at least a sub-pixel of a first color, a sub-pixel of a second color and a sub-pixel of a third color, and the first color, the second color and the third color are three primary colors, for example, red, green and blue. In some other examples, the pixel further includes a sub-pixel of a fourth color, and the fourth color is, for example, white.

The structure of the sub-pixel P will be described exemplarily below.

As shown in FIG. 3, each sub-pixel P includes, for example, a light-emitting unit 201. Each light-emitting unit 201 includes a first electrode 211, a light-emitting portion 221, and a second electrode 231 which are sequentially stacked in a direction away from a backplane 10. Each light-emitting unit 201 can emit light of a color, such as red light, green light and blue light. The first electrode 211 is an anode, and accordingly, the second electrode 231 is a cathode; alternatively, the first electrode 211 is a cathode, and accordingly, the second electrode 231 is an anode.

Each sub-pixel P further includes a pixel driving circuit coupled to the light-emitting unit 201. The pixel driving circuit is configured to drive the light-emitting unit 201 coupled thereto to emit light. The pixel driving circuit includes a transistor T, and an electrode (a first electrode S or a second electrode D) of the transistor T except a control electrode is electrically connected to the first electrode 211 of the light-emitting unit 201.

The film layer structure of the display panel 100 will be described exemplarily below.

In some embodiments, as shown in FIG. 3, the display panel 100 includes a backplane 10, and the backplane 10 includes a base substrate 11, a semiconductor layer, a first gate insulating layer GI1, a gate conductive layer Gate, a second gate insulating layer GI2 and a first source-drain conductive layer SD1 that are arranged in sequence.

For example, the base substrate 11 is a rigid substrate and/or a flexible substrate. A material of the rigid substrate includes, but is not limited to, glass, quartz and plastic. A material of the flexible substrate includes, but is not limited to, FPC, polyimide (PI), polycarbonate (PC) or polyvinyl chloride (PVC).

It will be noted that selection of the material of the base substrate 11 is related to the specific design of the display panel 100, and the material of the base substrate 11 may be selected depending on actual needs. The exemplary description is only made here, and is not used as limitations on the present disclosure.

For example, as shown in FIG. 3, the semiconductor layer includes an active layer 12 of each transistor T. The transistor T may be a low-temperature polysilicon thin film transistor, that is, the semiconductor layer is made of low-temperature polysilicon. The transistor T may alternatively be an oxide thin film transistor, that is, the semiconductor layer is made of metal oxide, such as indium gallium zinc oxide or indium gallium tin oxide.

For example, as shown in FIG. 3, the gate conductive layer Gate includes a gate conductive pattern. An orthographic projection of the gate conductive pattern on the base substrate 11 overlaps with an orthographic projection of the active layer 12 on the base substrate 11, and a portion of the gate conductive pattern overlapped with the active layer 12 serves as a control electrode G of each transistor T. The first electrode S and the second electrode D of the transistor T are located in the first source-drain conductive layer SD1.

In some embodiments, as shown in FIG. 3, the backplane 10 further includes a PI layer 14 disposed on the base substrate 11.

In a case where glass is selected as the material of the base substrate 11, forming the PI layer on the glass substrate may effectively reduce stress on the glass substrate in the subsequent manufacturing process of the backplane 10, so as to avoid cracks, breakage and other problems of the glass substrate due to stress during manufacturing the display panel 100, thereby improving a manufacturing yield of the display panel 100.

In some embodiments, as shown in FIG. 3, the backplane 10 further includes a buffer layer 13 disposed on the base substrate 11.

For example, the buffer layer 13 is disposed on the base substrate 11 and adhered to the base substrate 11; alternatively, the buffer layer 13 is disposed on a side of the PI layer 14 away from the base substrate 11.

During the subsequent manufacturing process of the display panel 100, for example, during forming the semiconductor layer, the gate conductive layer Gate, the first source-drain conductive layer SD1 and other film layer structures, the provision of the buffer layer 13 may effectively reduce the stress on the glass substrate in the subsequent manufacturing process of the backplane 10, so as to avoid cracks, breakage and other problems of the glass substrate due to stress during manufacturing the display panel 100, thereby improving the manufacturing yield of the display panel 100.

In some embodiments, as shown in FIG. 3, the backplane 10 further includes an interlayer dielectric layer ILD disposed between the gate conductive layer Gate and the first source-drain conductive layer SD1.

For example, a material of the interlayer dielectric layer ILD includes, but is not limited to, silicon oxide.

The interlayer dielectric layer ILD is formed between the gate conductive layer Gate and the first source-drain conductive layer SD1, so that electrical isolation is formed between the control electrode G of the transistor T and the first electrode S and the second electrode D of the transistor T. As a result, it may effectively reduce parasitic capacitance between the conductive material and the base substrate 11, thereby improving the parasitic field effect transistor formed by the conductive material spanning different areas.

Based on this, in some embodiments, as shown in FIG. 3, the display panel 100 further includes a light-emitting unit layer 20 disposed on the backplane 10. The light-emitting unit layer 20 is used to form a plurality of light-emitting units 201 in a plurality of sub-pixels P described above. The light-emitting unit layer 20 includes a first electrode layer 21, a pixel defining layer PDL, a light-emitting functional layer 22 and a second electrode layer 23 that are sequentially arranged in a direction away from the backplane 10.

For example, as shown in FIG. 3, a plurality of first electrodes 211 are located in the first electrode layer 21, and the plurality of first electrodes 211 are separated from each other. A plurality of light-emitting portions 221 are located in the light-emitting functional layer 22, and the plurality of light-emitting portions 221 are separated from each other. A plurality of second electrodes 231 are located in the second electrode layer 23.

Here, the plurality of second electrodes 231 are located in the second electrode layer 23, which means that the second electrode layer 23 includes the plurality of second electrodes 231, and the plurality of second electrodes 231 are connected to one another; or that as shown in FIG. 3, the second electrode layer 23 has a whole layer of film layer structure, and a portion of the second electrode layer 23 in an area defined by each light-emitting unit 201 serves as a second electrode 231 of the sub-pixel P. The first electrode layer 21 is an anode layer, and accordingly, the second electrode layer 23 is a cathode layer; alternatively, the first electrode layer 21 is a cathode layer, and accordingly, the second electrode layer 23 is an anode layer.

As shown in FIG. 3, the pixel defining layer PDL includes a plurality of first openings K1 corresponding to the plurality of first electrodes 211. Each first opening K1 exposes at least part of a first electrode 211, and at least part of each light-emitting portion 221 is located within a first opening K1.

For example, as shown in FIG. 3, the backplane 10 further includes: a first planarization layer PLN1 disposed between the first source-drain conductive layer SD1 and the light-emitting unit layer 20.

The provision of the first planarization layer PLN1 may fill a surface of the backplane 10 to be flat, so that each part of the backplane 10 has a substantially consistent film thickness, which is beneficial for maintaining a substantially consistent thickness of each film layer structure included in the light-emitting unit layer 20 during subsequent formation of the light-emitting unit layer 20, thereby ensuring a display uniformity of the display panel 100.

The description will be made below by considering an example where the second electrode layer 23 has a whole layer of film layer structure. It will be noted that for facilitating description of the specific structure of the display panel 100, the portion of the second electrode layer 23 corresponding to the sub-pixel P is referred to as a second electrode 231 of the sub-pixel P hereinafter.

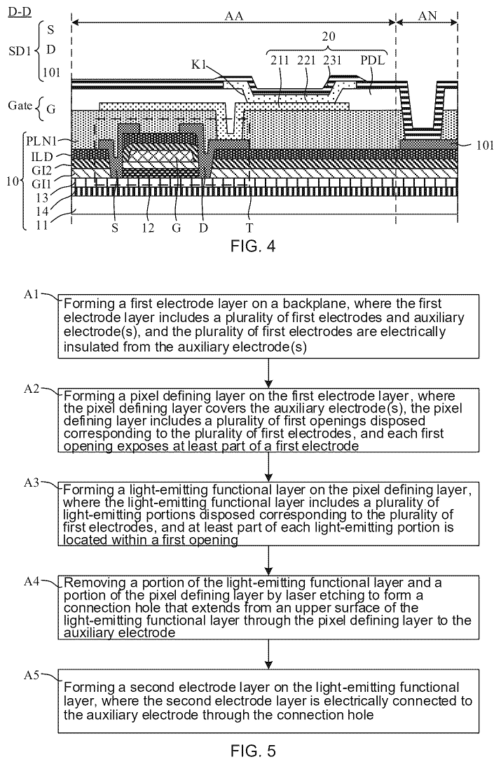

In some embodiments, as shown in FIG. 4, the backplane 10 includes a VSS bus 101 disposed on the base substrate 11, and the VSS bus 101 is disposed in the peripheral area AN. The VSS bus 101 is disposed at least on a side of the display area AA and extends into the bonding region BB.

For example, in a case where the backplane 10 has a single SD structure, that is, the backplane 10 includes a single source-drain conductive layer (i.e., the first source-drain conductive layer SD1), the VSS bus 101 may be located in the first source-drain conductive layer SD1 and/or in the gate conductive layer Gate.

In a case where the first electrode layer 21 is an anode layer and the second electrode layer 23 is a cathode layer, the second electrode layer 23 covers the display area AA, extends into the peripheral area AN and is electrically connected to the VSS bus 101. For example, as shown in FIG. 4, the second electrode layer 23 is connected to the VSS bus 101 in the backplane 10 through a hole in the peripheral area AN.

The arrangement of the VSS bus 101 will be described exemplarily below based on a case where the peripheral area AN surrounds the display area AA. It will be noted that the following is merely an exemplary description for a good understanding of the technical solution of the present disclosure, and is not intended to limit the present disclosure.

The VSS bus 101 may be disposed on a side of the display area AA and adjacent to the bonding region BB. An end of the VSS bus 101 proximate to the bonding region BB extends into the bonding region BB. Alternatively, the VSS bus 101 may also be disposed on remaining sides of the display area AA except a portion used for being bonded to the circuit board 200, and both ends of the VSS bus 101 extend from both sides of the bonding region BB into the bonding region BB. Alternatively, on a side of the display panel 100 bonded to the circuit board 200, a width of the peripheral area AN is greater than a width of the bonding region BB, and the VSS bus 101 may surround the display area AA and extend into the bonding region BB on a side of the display area AA proximate to the bonding region BB.

Distances between the second electrodes 231 of all the sub-pixels P in the display panel 100 and the VSS bus 101 are not exactly the same. When the display panel 100 emits light, each light-emitting unit 201 has the same driving current I. Thus, the greater the distance between the second electrode 231 and the VSS bus 101, the longer the transmission distance of the VSS signal transmitted from the VSS bus 101 to the second electrode 231, the greater the resistance R between the VSS bus 101 and the second electrode 231 along the transmission path of the VSS signal, and the lower the driving voltage U1 applied to the light-emitting unit 201 corresponding to the second electrode 231. Here, U1=U0-IR, where U0 is a target driving voltage applied to the light-emitting unit 201, and U1 is a driving voltage actually applied to the light-emitting unit 201.

It can be seen that as the size of the display panel 100 increases, the display panel 100 has an increasingly obvious IR Drop problem, so that the display uniformity of the display panel 100 becomes worse, and the display effect becomes worse.

It will be noted that in a case where the size of the display panel 100 is relatively large, for example, the size of the display panel 100 is greater than or equal to 16 inches, the IR Drop problem of the display panel 100 may cause poor display quality of the display panel 100. In a case where the size of the display panel 100 is smaller than 16 inches, the above problem may also occur in the display panel 100.

In addition, as the display brightness of the display panel 100 increases, for example, the peak brightness of the display panel 100 is greater than or equal to 800 nits, the driving current I required for the sub-pixel P to emit light also increases. In this way, the IR Drop problem of the display panel 100 becomes rather obvious, and the display uniformity of the display panel 100 decreases.

To solve the above problems, embodiments of the present disclosure provide a display panel 100 and a method for manufacturing the same. The structure of the display panel 100 and the method for manufacturing the same will be described below.

As shown in FIG. 5, the manufacturing method includes steps A1 to A5.

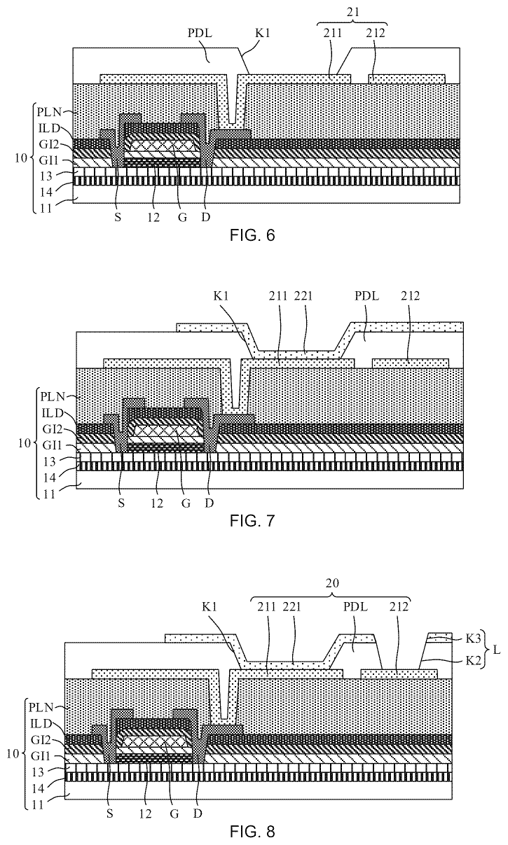

In A1, as shown in FIG. 6, a first electrode layer 21 is formed on a backplane 10. The first electrode layer 21 includes a plurality of first electrodes 211 and auxiliary electrode(s) 212. The plurality of first electrodes 211 are electrically insulated from the auxiliary electrode(s) 212.

For example, there may be one or more auxiliary electrodes 212, which may be adaptively designed depending on actual needs.

In A2, as shown in FIG. 6, a pixel defining layer PDL is formed on the first electrode layer 21. The pixel defining layer PDL covers the auxiliary electrode(s) 212. The pixel defining layer PDL includes a plurality of first openings K1 disposed corresponding to the plurality of first electrodes 211, and each first opening K1 exposes at least part of a first For example, the plurality of first electrodes 211 are separated from one another.

In A3, as shown in FIG. 7, a light-emitting functional layer 22 is formed on the pixel defining layer PDL. The light-emitting functional layer 22 includes a plurality of light-emitting portions 221 disposed corresponding to the plurality of first electrodes 211, and at least part of each light-emitting portion 221 is located within a first opening 221.

For example, the plurality of light-emitting portions 221 are separated from one another.

For example, in addition to the part of the light-emitting portion 221 located within the first opening K1, the light-emitting portion 221 further covers a sidewall of the first opening K1 and extends to an upper surface of the pixel defining layer PDL. The upper surface of the pixel defining layer PDL refers to a surface of the pixel defining layer PDL away from the backplane 10.

In A4, as shown in FIG. 8, a portion of the light-emitting functional layer 22 and a portion of the pixel defining layer PDL are moved by laser etching to form a connection hole L that extends from the upper surface of the light-emitting functional layer 22 through the pixel defining layer PDL to the auxiliary electrode 212.

The upper surface of the light-emitting functional layer 22 refers to a surface of the light-emitting functional layer 22 away from the backplane 10. The upper surface of the base substrate 11 refers to a surface of the base substrate 11 facing the light-emitting functional layer 22.

For example, the laser acts on the light-emitting functional layer 22 in a direction perpendicular to the upper surface of the base substrate 11. The laser etches away a portion of the light-emitting functional layer 22 to form a third opening K3 in the light-emitting functional layer 22 corresponding to the auxiliary electrode 212; then, the laser etches away a portion of the pixel defining layer PDL to form a second opening K2 in the pixel defining layer PDL corresponding to the auxiliary electrode 212; where the third opening K3 and the second opening K2 that are communicated constitute the connection hole L.

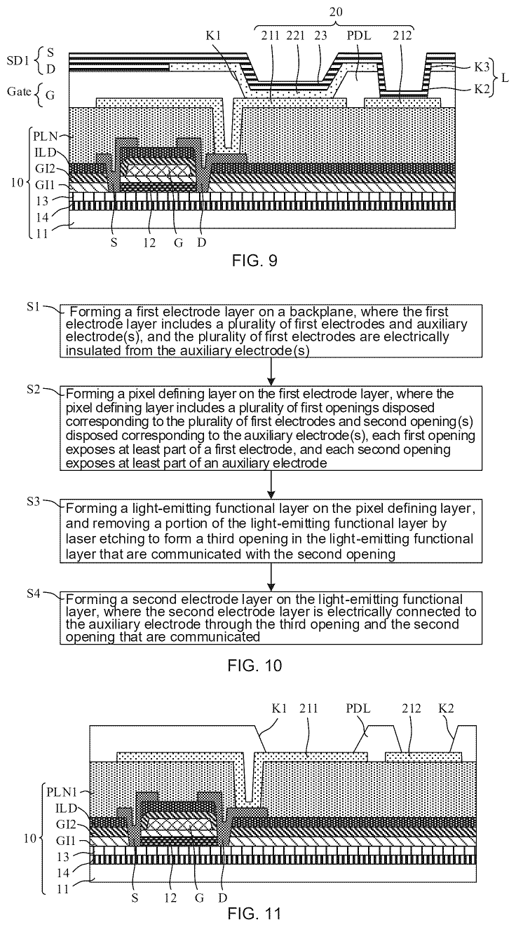

In A5, as shown in FIG. 9, a second electrode layer 23 is formed on the light-emitting functional layer 22. The second electrode layer 23 is electrically connected to the auxiliary electrode 212 through the connection hole L.

Accordingly, as shown in FIG. 9, in some embodiments, the display panel 100 is formed through the above-mentioned manufacturing method (steps A1 to A5). In the display panel 100, the first electrode layer 21 further includes at least one auxiliary electrode 212, and the first electrode 211 is electrically insulated from the auxiliary electrode 212. The pixel defining layer PDL further includes a second opening K2 disposed corresponding to the auxiliary electrode 212, and the second opening K2 exposes at least part of the auxiliary electrode 212. The light-emitting functional layer 22 includes a third opening K3, and the third opening K3 is communicated with the second opening K2. The second electrode layer 23 is electrically connected to the auxiliary electrode 212 through the third opening K3 and the second opening K2 that are communicated. The auxiliary electrode 212, the second opening K2 and the third opening K3 are all located in the display area AA. The second electrode layer 23 covers sidewalls of the second opening K2 and the third opening K3.

The second electrode layer 23 is electrically connected to the auxiliary electrode 212 through the communicated openings in the light-emitting functional layer 22 and the pixel defining layer PDL. Thus, a resistance of the second electrode layer 23 may be reduced, thereby reducing the power consumption of the display panel 100; moreover, an impact of the IR Drop problem of the display panel 100 may also be reduced, thereby improving the display uniformity of the display panel 100.

The auxiliary electrode 212 is provided in the first electrode layer 21, so that the auxiliary electrode 212 may be formed together with the first electrodes 211, thereby improving the display uniformity of the display panel 100 and reducing the power consumption of the display panel 100 without adding manufacturing steps of the display panel 100.

In a case where the display panel 100 has a relatively low pixel density, for example, the pixel density of the display panel 100 is less than 450 PPI, the display panel 100 may adopt the structure in the above embodiments and/or may be formed using the manufacturing method in the above embodiments.

In a case where the display panel 100 has a relatively high pixel density, for example, the pixel density of the display panel 100 is greater than or equal to 450 PPI, when the connection hole L is formed by laser etching, the laser needs to etch through the light-emitting functional layer 22 and the pixel defining layer PDL in sequence from a direction. In this way, the laser etching depth is relatively large. During laser etching, the laser energy may cause damage to the light-emitting portion 221 adjacent to the connection hole L, thereby affecting a light-emitting effect of the light-emitting unit 201.

In light of this, embodiments of the present disclosure provide another display panel 100 and a method for manufacturing the same. The structure of the display panel 100 and the method for manufacturing the same will be described below.

As shown in FIG. 10, the manufacturing method includes steps S1 to S4.

In S1, as shown in FIG. 11, a first electrode layer 21 is formed on a backplane 10. The first electrode layer 21 includes a plurality of first electrodes 211 and auxiliary electrode(s) 212. The plurality of first electrodes 211 are electrically insulated from the auxiliary electrode(s) 212.

In S2, as shown in FIG. 11, a pixel defining layer PDL is formed on the first electrode layer 21. The pixel defining layer PDL includes a plurality of first openings K1 disposed corresponding to the plurality of first electrodes 211 and second opening(s) K2 disposed corresponding to the auxiliary electrode(s) 212. Each first opening K1 exposes at least part of a first electrode 211, and each second opening K2 exposes at least part of an auxiliary electrode 212.

For example, the second opening K2 and the first opening K1 may be formed simultaneously or separately. For example, a whole layer of pixel defining layer PDL is formed, and then the first openings K1 and the second opening(s) K2 are formed in the pixel defining layer PDL. The second opening(s) K2 and the first openings K1 may be formed simultaneously by photolithography.

For example, the second opening(s) K2 may be formed by laser etching. In this way, when the second opening K2 is formed by laser etching, the laser energy used may be relatively small due to the relatively small laser etching depth, thereby preventing the laser energy from damaging the adjacent light-emitting portion 221.

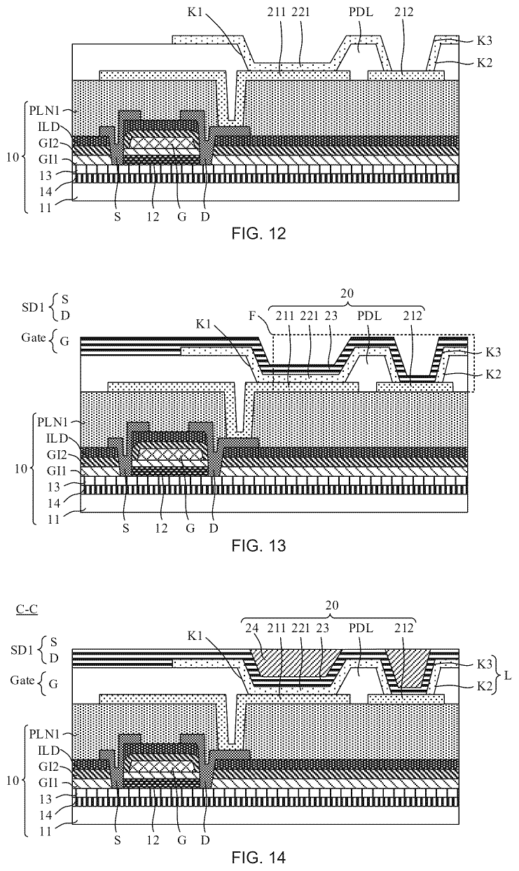

In S3, as shown in FIG. 12, a light-emitting functional layer 22 (which may be understood here as a light-emitting functional layer film for forming the light-emitting functional layer) is formed on the pixel defining layer PDL. A portion of the light-emitting functional layer 22 is moved by laser etching to form a third opening K3 in the light-emitting functional layer 22 that are communicated with the second opening K2.

In the step S3, when a portion of the light-emitting functional layer 22 in contact with the auxiliary electrode 212 is removed by laser etching, the auxiliary electrode 212 is exposed. In this way, the laser etching depth is relatively small, and therefore the laser energy used may be relatively small when the third opening K3 is formed by laser etching, thereby preventing the laser energy from damaging the adjacent light-emitting portion 221.

For example, the laser used in the step S3 is UV light, pulsed laser, fluorescent laser light or the like.

For example, the light-emitting functional layer 22 covers a sidewall of the second opening K2.

For example, the third opening K3 may be formed by photolithography or laser etching.

In S4, as shown in FIG. 13, a second electrode layer 23 is formed on the light-emitting functional layer 22. The second electrode layer 23 is electrically connected to the auxiliary electrode 212 through the third opening K3 and the second opening K2 that are communicated.

Accordingly, as shown in FIG. 13, in some embodiments, the display panel 100 is formed through the above-mentioned manufacturing method (steps S1 to S4).

The display panel 100 formed through the steps S1 to S4 has the same beneficial effects as the display panel 100 formed through the steps A1 to A5. Moreover, compared with the display panel 100 formed through the steps A1 to A5, it may avoid damage to the light-emitting functional layer 22 by laser energy during the manufacturing process of the display panel 100, thereby ensuring the display effect of the display panel 100.

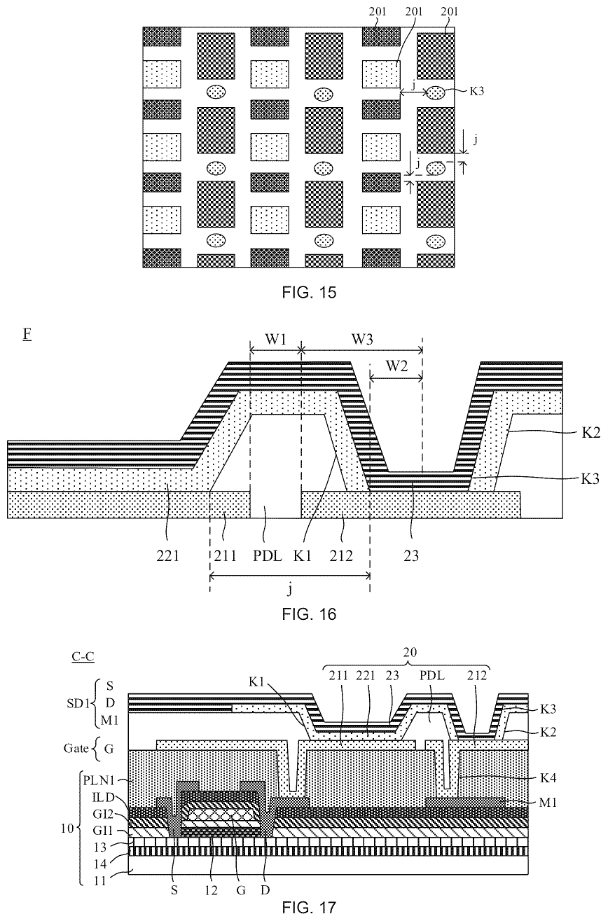

FIG. 15 is a partial enlarged view of a display area AA of a display panel 100 in accordance with some embodiments. For facilitating clear description of the relative position between the third opening K3 and the light-emitting unit 201, FIG. 15 only shows the light-emitting portions 221 of the plurality of light-emitting units 201 and a plurality of third openings K3.

In some embodiments, as shown in FIG. 13, the pixel defining layer PDL includes a plurality of first openings K1 disposed corresponding to the plurality of first electrodes 211 and second opening(s) K2 disposed corresponding to the auxiliary electrode(s) 212. Each first opening K1 exposes at least part of a first electrode 211, and a second opening K2 exposes at least part of an auxiliary electrode 212. The light-emitting functional layer 22 includes third opening(s) K3, and a third opening K3 is communicated with a second opening K2. The second electrode layer 23 is electrically connected to the auxiliary electrode 212 through the third opening K3 and the second opening K2 that are communicated. The auxiliary electrode 212, the second opening K2 and the third opening K3 are all located in the display area AA.

The auxiliary electrode 212 is added in the first electrode layer 21, and the second electrode layer 23 is in contact with the auxiliary electrode 212 after passing through the third opening K3 in the light-emitting functional layer 22 and the second opening K2 in the pixel defining layer PDL, so as to reduce the resistance of the second electrode layer 23, thereby reducing the power consumption of the display panel 100. Moreover, the impact of the IR Drop problem of the display panel 100 may also be effectively reduced, thereby improving the display uniformity of the display panel 100.

Before the light-emitting functional layer 22 is formed, the second opening K2 has been formed in the pixel defining layer PDL. The second opening K2 and the first openings K1 may be formed in the same step without adding additional manufacturing steps. Furthermore, before the second electrode layer 23 is formed, it is only necessary to remove the portion of the light-emitting functional layer 22 in contact with the auxiliary electrode 212, so that the second electrode layer 23 and the auxiliary electrode 212 may be in contact and electrically connected.

The third opening K3 may be formed by photolithography or laser etching, which has a high manufacturing flexibility. Moreover, the light-emitting functional layer 22 has a relatively small thickness, and when the third opening K3 is formed by laser etching, the laser energy used is also relatively small, so as to avoid damage to the portion of the light-emitting functional layer 22 adjacent to the third opening K3 by laser energy, thereby ensuring the display effect of the display panel 100.

In some embodiments, as shown in FIG. 14, the display panel 100 further includes at least one third electrode 24 disposed on a side of the second electrode layer 23 away from the backplane 10. The third electrode 24 may be disposed corresponding to the first electrode 211 and/or disposed corresponding to the auxiliary electrode 212.

The provision of the third electrode(s) 24 may reduce the resistance of the second electrode layer 23, thereby reducing the power consumption of the display panel 100.

FIG. 15 is a partial enlarged view of a display area AA of the display panel 100. To clearly illustrate distribution of the third openings K3 in the display area AA, FIG. 15 only shows the light-emitting units 201 and the third openings K3.

In some embodiments, as shown in FIG. 15, the light-emitting functional layer 22 includes a plurality of third openings K3, and the plurality of third openings K3 are evenly distributed in the display area AA.

The first electrode layer 21 includes a plurality of auxiliary electrodes 212. In this way, the light-emitting function layer 22 includes the plurality of third openings K3, and the pixel defining layer PDL includes the plurality of second openings K2. The greater the number of auxiliary electrodes 212 connected to the second electrode layer 23, the better the effect of reducing the resistance of the second electrode layer 23, and the better the effect of reducing the power consumption of the display panel 100.

Moreover, the plurality of third openings K3 are evenly distributed in the display area AA, and accordingly, the plurality of auxiliary electrodes 212 are also evenly distributed in the display area AA. In this way, the second electrode layer 23 may have a plurality of evenly distributed positions for reducing resistance in the display area AA, so as to achieve a rather good effect of reducing a screen cross-voltage of the display panel 100. As a result, the display panel 100 may have a rather good display uniformity and a rather good display effect.

It will be noted that there is at least one auxiliary electrode 212, and accordingly, there is at least one third opening K3 and at least one second opening K2. The second electrode layer 23 is in contact with the auxiliary electrode 212 through the third opening K3 and the second opening K2 that are communicated to achieve electrical connection. Therefore, the more the number of the auxiliary electrode(s) 212, the more the number of the third opening(s) K3 and the second opening(s) K2 accordingly.

For example, in a case where the display panel 100 includes a plurality of third openings K3, a distance between centers of the plurality of third openings K3 is greater than or equal to 0.1 mm and less than or equal to 10 mm.

It will be noted that a range of the distance between the third openings K3 given here in the case where the light-emitting functional layer 22 includes the plurality of third openings K3 is not limited to the above range (0.1 mm to 10 mm), and may also be smaller or larger. The adaptive design is carried out specifically depending on actual needs. The above is only an exemplary description, and is not intended to limit the present disclosure.

In some embodiments, FIG. 16 is an enlarged view showing a structure of an area F in FIG. 13. As shown in FIG. 16, an orthogonal projection of the third opening K3 on the backplane 10 falls within an orthographic projection of the auxiliary electrode 212 on the backplane 10, and there is a distance between an edge of the third opening K3 and an edge of the auxiliary electrode 212.

In this way, when the third opening K3 is formed, the third opening K3 only exposes at least part of an upper surface of the auxiliary electrode 212, thereby ensuring effective connection between the second electrode layer 23 and the auxiliary electrode 212.

In some embodiments, as shown in FIG. 16, the first electrode 211 and the auxiliary electrode 212 that are adjacent have a distance W1 therebetween, where W1≥2 μm.

Limiting the distance between the first electrode 211 and the auxiliary electrode 212 may effectively avoid short circuit due to conduction of the first electrode layer 21 and the second electrode layer 23 caused by contact between the first electrode 211 and the auxiliary electrode 212. It is beneficial to achieving a high pixel density of the display panel 100 and improving the display quality while reducing the power consumption of the display panel 100 and improving the display uniformity of the display panel 100.

The auxiliary electrode 212 is disposed in the same layer as the plurality of first electrodes 211, that is, the auxiliary electrode 212 is disposed in an interval area between the plurality of first electrodes 211. The larger the distance between the auxiliary electrode 212 and the first electrode 211, the larger the distance between adjacent first electrodes 211, that is, the larger the distance between adjacent light-emitting units 201, and the lower the pixel density of the display panel 100.

In some embodiments, as shown in FIG. 16, an orthogonal projection of the third opening K3 on the backplane 10 falls within an orthogonal projection of the second opening K2 on the backplane 10. A center of the third opening K3 and an edge of the third opening K3 have a distance W2 therebetween, where W2≥8 μm.

A size of the third opening K3 is related to a contact area between the second electrode layer 23 and the auxiliary electrode 212. Therefore, the size of the third opening K3 should at least meet an effective contact between the second electrode layer 23 and the auxiliary electrode 212, thereby ensuring electrical connection between the second electrode layer 23 and the auxiliary electrode 212.

Controlling the distance between the center of the third opening K3 and the edge of the third opening K3 may ensure that the size of the third opening K3 can meet the requirements for effective connection between the second electrode layer 23 and the auxiliary electrode 212.

In some embodiments, as shown in FIG. 16, centers of the second opening K2 and the third opening K3 coincide with each other, and a center of the second opening K2 and an edge of the auxiliary electrode 212 have a distance W3 therebetween, where W3≥9.5 μm.

Controlling the distance between the center of the second opening K2 and the edge of the auxiliary electrode 212 may ensure that a position of the second opening K2 is within an upper surface of the auxiliary electrode 212, so as to ensure effective connection between the second electrode layer 23 formed subsequently and the auxiliary electrode 212, thereby avoiding breakage of the second electrode layer 23 in the second opening K2 and the third opening K3.

It can be seen in combination with the above embodiments that a distance between the edge of the third opening K3 and the edge of the auxiliary electrode 212 is (W3−W2) that is greater than or equal to 1.5 μm (W3−W2≥1.5 μm). Thus, it may further ensure that a portion of the second electrode layer 23 located in the third opening K3 and the second opening K2 is located on the auxiliary electrode 212, thereby ensuring the effective connection between the second electrode layer 23 and the auxiliary electrode 212.

In some embodiments, as shown in FIGS. 15 and 16, the third opening K3 is located between two adjacent light-emitting units 201, and there is a gap j between the third opening K3 and an adjacent light-emitting unit 201.

As shown in FIG. 15, the plurality of light-emitting units 201 include light-emitting units 201 of at least three different colors. The light-emitting units 201 of different colors may have the same size or not exactly the same sizes. Any two adjacent light-emitting units 201 may have the same distance therebetween or not exactly the same distance therebetween.

The distance between two adjacent light-emitting units 201 mentioned here refers to a distance between light-emitting areas of the two adjacent light-emitting units 201. This distance may be a distance between two adjacent first openings K1 in the pixel defining layer PDL.

In a case where any two adjacent light-emitting units 201 have the same distance therebetween, the third opening K3 may be provided between any two adjacent light-emitting units 201. In a case where any two adjacent sub-pixels P have not exactly the same distance therebetween, the second opening K2 and the third opening K3 may be provided between any two adjacent sub-pixels P, or between two adjacent sub-pixels P with a relatively large distance therebetween.

In some embodiments, as shown in FIG. 17, the first source-drain conductive layer SD1 is disposed between the base substrate 11 and the first electrode layer 21. The first source-drain conductive layer SD1 further includes a first conductive pattern M1 located in the display area AA. The first planarization layer PLN1 is disposed between the first source-drain conductive layer SD1 and the first electrode layer 21. The first planarization layer PLN1 includes a fourth opening K4. The auxiliary electrode 212 is electrically connected to the first conductive pattern M1 through the fourth opening K4. The first electrode S and the second electrode D of the transistor T are disposed in the same layer as the first conductive pattern M1. In this way, without adding additional manufacturing steps, the resistance of the second electrode layer 23 may further be reduced, thereby well reducing the power consumption of the display panel 100 and improving the display uniformity of the display panel 100.

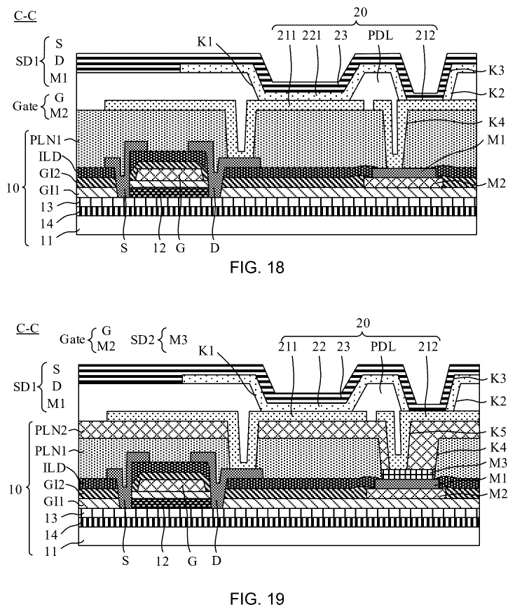

In some embodiments, as shown in FIG. 18, the backplane 10 further includes: a second conductive pattern M2 included in the gate conductive layer Gate and located in the display area AA, and the second conductive pattern M2 is electrically connected to the first conductive pattern M1.

For example, the interlayer dielectric layer ILD is provided with a via hole therein, and the second conductive pattern M2 is in contact with the first conductive pattern M1 through the via hole in the interlayer dielectric layer ILD to achieve electrical connection.

The control electrode of the transistor T is disposed in the same layer as the second conductive pattern M2. In this way, without adding additional manufacturing steps, the resistance of the second electrode layer 23 may further be reduced, thereby well reducing the power consumption of the display panel 100 and improving the display uniformity of the display panel 100.

In some embodiments, as shown in FIG. 19, the backplane 10 further includes: a second source-drain conductive layer SD2 disposed between the first planarization layer PLN1 and the first electrode layer 21, and a second planarization layer PLN2 disposed between the second source-drain conductive layer SD2 and the first electrode layer 21. The second source-drain conductive layer SD2 includes a third conductive pattern M3 located in the display area AA. The second planarization layer PLN2 includes a fifth opening K5. The auxiliary electrode 212 is electrically connected to the third conductive pattern M3 through the fifth opening K5. The third conductive pattern M3 is electrically connected to the first conductive pattern M1.

The third conductive pattern M3 is provided to allow the second electrode layer 23 to be electrically connected to the auxiliary electrode 212, the first conductive pattern M1 and the second conductive pattern M2, so that the resistance of the second electrode layer 23 may further be reduced, thereby well reducing the power consumption of the display panel 100 and improving the display uniformity of the display panel 100.

It will be noted that in a case where the backplane 10 has a single SD structure, that is, the backplane 10 includes a single source-drain conductive layer (i.e., the first source-drain conductive layer SD1), the auxiliary electrode 212 is directly in contact with the first conductive pattern M1 through the fourth opening K4 in the first planarization layer PLN1 to achieve electrical connection.

In a case where the backplane 10 has a dual SD structure, that is, the backplane 10 includes two source-drain conductive layers (i.e., the first source-drain conductive layer SD1 and the second source-drain conductive layer SD2), the auxiliary electrode 212 is first in contact with the third conductive pattern M3 located in the fourth opening K4 through the fifth opening K5 in the second planarization layer PLN2 to achieve electrical connection; and since the third conductive pattern M3 is electrically connected to the first conductive pattern M1, the auxiliary electrode 212 may be electrically connected to the first conductive pattern M1 by the third conductive pattern M3.

In some embodiments, as shown in FIGS. 17, 18, 19 and 20, at least one of the first conductive pattern M1, the second conductive pattern M2 and the third conductive pattern M3 is a VSS auxiliary signal line.

For example, at least one of the first conductive pattern M1, the second conductive pattern M2 and the third conductive pattern M3 that are disposed in the display area AA is electrically connected to the VSS bus 101 disposed in the peripheral area AN.

In this way, as a conductive pattern M (at least one of the first conductive pattern M1, the second conductive pattern M2 and the third conductive pattern M3) for transmitting the VSS signal, the conductive pattern M transmits the VSS signal from the display area AA to the second electrode layer 23. While reducing the resistance of the second electrode layer 23, a length of a transmission path of the VSS signal to the second electrode 231 may also be reduced, so as to reduce a voltage difference between the light-emitting units 201 at a periphery region of the conductive pattern M, and further reduce the impact of the IR Drop problem of the display panel 100, thereby improving the display uniformity of the display panel 100.

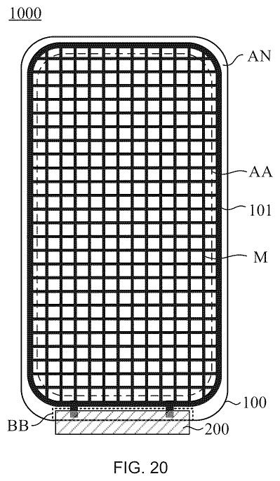

The display panel 100 and the circuit board 200 shown in FIG. 20 has a structure as shown in a structural diagram of the display device 1000 during bonding the display panel 100 to the circuit board 200. In an actually formed display device 1000, a portion of the circuit board 200 that extends beyond the display panel 100 is bent to another side of For example, during the manufacturing process of the display device 1000, an end of the circuit board 200 is bonded to the display panel 100 at a display side (the display side is a side of the display panel 100 provided with the light-emitting unit layer, and the circuit board 200 may be electrically connected to the bonding region BB of the display panel 100 at the display side), and then another end of the circuit board 200 is bent to the other side of the display panel 100 opposite to the display side, so as to obtain the display device 1000 shown in FIG. 2.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

What is claimed is:

1. A display panel, having a display area, and the display panel comprising:
a backplane;
a light-emitting unit layer disposed on the backplane; wherein the light-emitting unit layer includes a first electrode layer, a pixel defining layer, a light-emitting functional layer and a second electrode layer that are sequentially arranged in a direction away from the backplane, wherein
the first electrode layer includes a plurality of first electrodes and at least one auxiliary electrode, and the plurality of first electrodes are electrically insulated from the at least one auxiliary electrode;
the pixel defining layer includes a plurality of first openings disposed corresponding to the plurality of first electrodes, and at least one second opening disposed corresponding to the at least one auxiliary electrode; each first opening exposes at least part of a first electrode, and a second opening exposes at least part of an auxiliary electrode;
the light-emitting functional layer includes at least one third opening, a third opening is communicated with the second opening, and the second electrode layer is electrically connected to the auxiliary electrode through the third opening and the second opening that are communicated; and
the at least one auxiliary electrode, the at least one second opening and the at least one third opening are all located in the display area.

2. The display panel according to claim 1, wherein an orthogonal projection of the third opening on the backplane falls within an orthographic of the auxiliary electrode on the backplane, and an edge of the third opening and an edge of the auxiliary electrode have a distance therebetween.

3. The display panel according to claim 1, wherein a first electrode and the auxiliary electrode that are adjacent have a distance W1 therebetween, and W1≥2 μm.

4. The display panel according to claim 1, wherein the light-emitting unit layer covers a sidewall of the second opening.

5. The display panel according to claim 1, wherein the display panel comprises a plurality of sub-pixels located in the display area, and each sub-pixel includes a first electrode, a portion of the light-emitting functional layer corresponding to the first electrode and a portion of the second electrode layer corresponding to the first electrode; and
the second opening and the third opening are located between two adjacent sub-pixels, and a whole of the second opening and the third opening and an adjacent sub-pixel have a gap therebetween.

6. The display panel according to claim 1, wherein the light-emitting functional layer includes a plurality of third openings, and the plurality of third openings are evenly distributed in the display area.

7. The display panel according to claim 1, wherein an orthogonal projection of the third opening on the backplane falls within an orthogonal projection of the second opening on the backplane; and
a center of the third opening and an edge of the third opening have a distance W2 therebetween, and W2≥8 μm.

8. The display panel according to claim 1, wherein centers of the second opening and the third opening coincide with each other, and a center of the second opening and an edge of the auxiliary electrode have a distance W3 therebetween, and W3≥9.5 μm.

9. The display panel according to claim 1, wherein the backplane includes:
a base substrate;
a first source-drain conductive layer disposed between the base substrate and the first electrode layer, wherein the first source-drain conductive layer includes a first conductive pattern located in the display area; and
a first planarization layer disposed between the first source-drain conductive layer and the first electrode layer, wherein the planarization layer includes a fourth opening, and the auxiliary electrode is electrically connected to the first conductive pattern through the fourth opening.

10. The display panel according to claim 9, wherein the backplane further includes:
a gate conductive layer disposed between the first source-drain conductive layer and the base substrate, wherein the gate conductive layer includes a second conductive pattern located in the display area, and the second conductive pattern is electrically connected to the first conductive pattern.

11. The display panel according to claim 10, wherein the backplane further includes:
a second source-drain conductive layer disposed between the first planarization layer and the first electrode layer, wherein the second source-drain conductive layer includes a third conductive pattern located in the display area; and
a second planarization layer disposed between the second source-drain conductive layer and the first electrode layer, wherein the second planarization layer includes a fifth opening, the auxiliary electrode is electrically connected to the third conductive pattern through the fifth opening, and the third conductive pattern is electrically connected to the first conductive pattern through the fourth opening.

12. The display panel according to claim 11, wherein at least one of the first conductive pattern, the second conductive pattern and the third conductive pattern is a VSS auxiliary signal line.

13. The display panel according to claim 1, wherein a pixel density of the display panel is greater than or equal to 450 PPI.

14. A display device, comprising:
the display panel according to claim 1; and
a circuit board electrically connected to the display panel.

15. A method for manufacturing a display panel, comprising:
forming a first electrode layer on a backplane, wherein the first electrode layer includes a plurality of first electrodes and an auxiliary electrode, and the plurality of first electrodes are electrically insulated from the auxiliary electrode;
forming a pixel defining layer on the first electrode layer, wherein the pixel defining layer includes a plurality of first openings disposed corresponding to the plurality of first electrodes, and a second opening disposed corresponding to the auxiliary electrode; each first opening exposes at least part of a first electrode, and the second opening exposes at least part of the auxiliary electrode;
forming a light-emitting functional layer on the pixel defining layer, and removing a portion of the light-emitting functional layer by laser etching to form a third opening in the light-emitting functional layer that that is communicated with the second opening; and
forming a second electrode layer on the light-emitting functional layer, wherein the second electrode layer is electrically connected to the auxiliary electrode through the third opening and the second opening that are communicated.

16. The display panel according to claim 6, wherein a distance between centers of the plurality of third openings is greater than or equal to 0.1 mm and less than or equal to 10 mm.

17. The display panel according to claim 1, wherein the second electrode layer includes a plurality of second electrodes that are connected to one another; or the second electrode layer has a whole layer of film layer structure.

18. The display panel according to claim 1, further comprising at least one third electrode disposed on a side of the second electrode layer away from the backplane, wherein the at least one third electrode is disposed corresponding to the first electrode and/or corresponding to the auxiliary electrode.
